(19) United States
(12) Patent Application Publication
(10) Pub. No.: US 2012/0073646 A1
(43) Pub. Date: Mar. 29, 2012

(54) Solar Cell And Method Of Fabricating The Same

(75) Inventors: Suk Jae Jee, Seoul (KR); Sung Bum Choi, Seoul (KR)

(73) Assignee: LG INNOTEK CO., LTD., Seoul (KR)

(21) Appl. No.: 13/375,310

(22) PCT Filed: Jun. 16, 2010
(86) PCT No.: PCT/KR10/03888

§ 371 Date: Nov. 30, 2011

(30) Foreign Application Priority Data
Jun. 16, 2009 (KR) 10-2009-0053229

(51) Int. Cl. H01L 31/0224; H01L 31/18

(52) U.S. Cl. 136/256; 438/98; 257/E31.124

(57) ABSTRACT

Disclosed are a solar cell and a method of fabricating the same. The solar cell includes a substrate, a rear electrode layer provided on the substrate, a light absorbing layer provided on the rear electrode, and a front electrode layer provided on the light absorbing layer. The rear electrode layer includes a first conductive layer provided on the substrate, a second conductive layer provided on the first conductive layer and having a grain size different from a grain size of the first conductive layer, and a third conductive layer provided on the second conductive layer and having a grain size different from the grain size of the second conductive layer.

### TECHNICAL FIELD

The embodiment relates to a solar cell and a method of fabricating the same.

### BACKGROUND ART

Recently, as demand for energy is increased, a solar cell has been developed to convert solar energy into electrical energy.

Especially, a CIGS-based solar cell serving as a PN hetero junction device has been extensively used. The CIGS-based solar cell has a substrate structure including a glass substrate, a metal rear electrode layer, a P type CIGS-based light absorbing layer, a high resistant buffer layer, and an N type window layer.

Such a solar cell satisfies the adhesion strength and the conductivity of the rear electrode layer to represent improved efficiency.

### DISCLOSURE OF INVENTION

### Technical Problem

The embodiment provides a solar cell having improved performance and a method of fabricating the same.

### Solution to Problem

According to the embodiment, the solar cell includes a substrate, a rear electrode layer provided on the substrate, a light absorbing layer provided on the rear electrode, and a front electrode layer provided on the light absorbing layer. The rear electrode layer includes a first conductive layer provided on the substrate, a second conductive layer provided on the first conductive layer and having a grain size different from a grain size of the first conductive layer, and a third conductive layer provided on the second conductive layer and having a grain size different from the grain size of the second conductive layer.

According to the embodiment, the solar cell includes a substrate, a rear electrode layer provided on the substrate, a light absorbing layer provided on the rear electrode layer, and a front electrode layer provided on the light absorbing layer. The rear electrode layer includes at least three conductive layers. Two adjacent conductive layers among the conductive layers have grain sizes different from each other.

According to the embodiment, a method of fabricating a solar cell includes forming a rear electrode layer on a substrate, forming a light absorbing layer on the rear electrode layer, and forming a front electrode layer on the light absorbing layer. The forming of the rear electrode layer includes forming a first conductive layer on the substrate by using first power, forming a second conductive layer on the first conductive layer by using second power different from the first power, and forming a third conductive layer on the second conductive layer by using third power different from the second power.

### Advantageous Effects of Invention

The solar cell according to the embodiment includes a rear electrode including a plurality of conductive layers. In this case, the conductive layers may have grain sizes different from each other. Accordingly, the conductive layers can have different characteristics.

Therefore, the conductive layers can compensate each other for inferior characteristics, and improve the whole characteristic of the rear electrode. For example, conductive layers having greater grain sizes can improve the electrical characteristic of the rear electrode layer, and the conductive layers having a smaller grain size can improve the mechanical characteristic of the rear electrode layer. In particular, the conductive layers having smaller grain sizes can be filled in voids of the conductive layers having greater grain sizes.

In order to realize such a rear electrode layer, a sputtering device, in which the first and second cathodes of receiving different power are arranged, can be used. In other words, at least three conductive layers can constitute the rear electrode layer by the sputtering device including two cathodes to receive different power.

The first cathode receives low power, and the second cathode receives high power, so that conductive layers adjacent to each other have different grain sizes. Accordingly, the adhesion property and the conductivity of the rear electrode layer can be simultaneously satisfied.

In addition, since the conductive layers can be sequentially formed in one chamber, the solar cell according to the embodiment having improved characteristics can be manufactured through the method of fabricating the solar cell with improved productivity.

### BRIEF DESCRIPTION OF DRAWINGS

FIG. 1 is a view schematically showing a solar cell fabrication apparatus for fabricating a rear electrode layer of a solar cell according to the embodiment;

FIG. 2 is a sectional view showing the rear electrode layer of the solar cell according to the embodiment; and

FIGS. 3 to 6 are sectional views showing a method of fabricating a solar cell according to the embodiment.

### MODE FOR THE INVENTION

In the description of an embodiment, it will be understood that, when a substrate, a layer, a film, or an electrode is referred to as being “on” or “under” another substrate, another layer, another film, or another electrode, it can be “indirectly” or “directly” on the other substrate, layer, film, electrode or one or more intervening layers may also be present. Further, “on” or “under” of each layer is determined based on the drawing. Further, “on” or “under” of each layer is determined based on the drawing. The thickness or size of layers shown in the drawings can be simplified or exaggerated for the purpose of clear explanation. In addition, the size of each element may be reduced or magnified from the real size thereof.

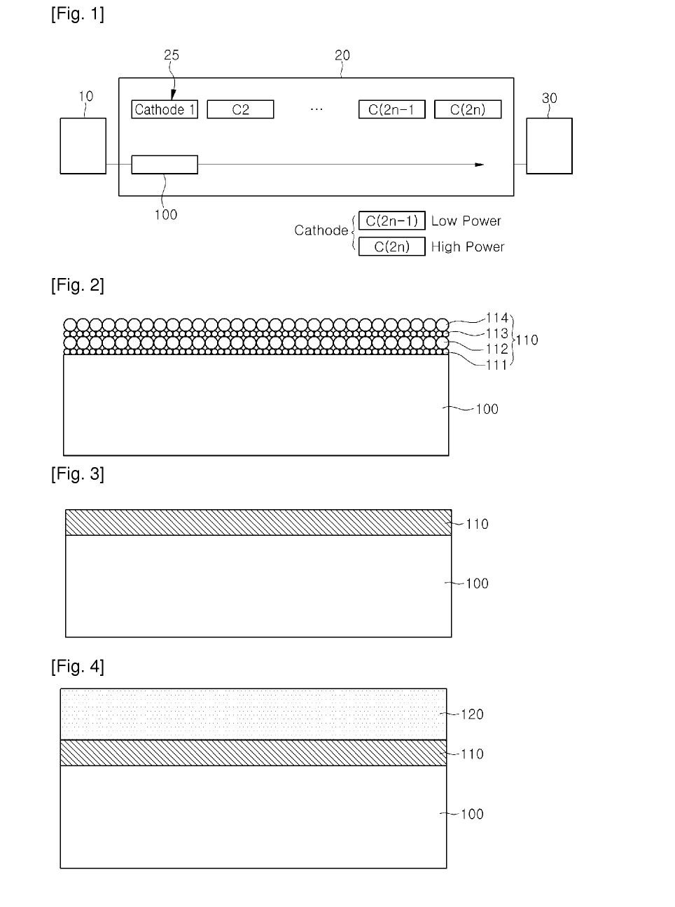

FIGS. 1 to 6 are views showing a method of fabricating a solar cell according to the embodiment. In particular, FIG. 1 is a view showing a solar cell fabrication apparatus to form a rear electrode layer of the solar cell. FIGS. 2 and 3 are sectional views showing the rear electrode layer of the solar cell formed by the solar cell fabrication apparatus.

Referring to FIGS. 1 to 3, a rear electrode layer 110 is formed on a substrate 100.

The substrate 100 may include glass, ceramic, metal, or polymer. For example, the glass substrate 100 may include sodalime glass or high strained point soda glass. The substrate 100 may be transparent. The substrate 100 may be rigid or flexible.

The rear electrode layer 110 is formed on the substrate 100. The rear electrode layer 110 may include a conductor made of metal. The rear electrode layer 110 includes metal to improve series resistance and increase electrical conductivity. For example, the rear electrode layer 110 may have a thickness in the range of about 500 nm to about 1500 nm, and may have resistance in the range of about 0.15Ω/□ to about 0.25Ω/□.

The rear electrode layer 110 may include molybdenum (Mo). The rear electrode layer 110 is not limited to Mo, but may include Mo doped with sodium (Na). This is because Mo represents high conductivity, an ohmic contact characteristic with a light absorption layer, and high temperature stability at a Se (selenium) atmosphere.

The Mo thin film constituting the rear electrode layer 110 must have low resistivity in order to act as an electrode, and must have a superior adhesion property with the substrate 100 such that delamination caused by the difference in a thermal expansion coefficient does not occur.

As shown in FIG. 2, the rear electrode layer 110 may include a plurality of conductive layers. In other words, the rear electrode layer 110 may have a stack structure of the conductive layers. At least three conductive layers may be provided. In more detail, the number of the conductive layers may be in the range of 3 to 10.

For example, the rear electrode layer 110 may include a first conductive layer 111, a second conductive layer 112, a third conductive layer 113, and a fourth conductive layer 114. In addition, although not shown in FIG. 2, conductive layers may be additionally stacked on the fourth conductive layer 114. For example, fifth to tenth conductive layers may be additionally stacked on the fourth conductive layer 114.

The first conductive layer 111 is provided on the substrate 100, and the second conductive layer 112 is provided on the first conductive layer 111. The third conductive layer 113 is provided on the second conductive layer 112. The fourth conductive layer 114 is provided on the third conductive layer 113.

The first to fourth conductive layers 111 to 114 include the same material. In more detail, the first to fourth conductive layers 111 to 114 consist of the same material. For example, the first to fourth conductive layers 111 to 114 may include Mo that has been described above.

The first to fourth conductive layers 111 to 114 may have grains in different sizes. For example, the grains of adjacent conductive layers among the first to fourth conductive layers 111 to 114 may have different sizes. Since the adjacent conductive layers are formed under different process conditions, the grains of the adjacent conductive layers have different sizes. For example, since the adjacent conductive layers are formed under different power conditions, the grains of the adjacent conductive layers may have different sizes. In detail, the adjacent conductive layers may be formed through sputtering process under different power conditions. Accordingly, the grains of the adjacent conductive layers may have different sizes.

For example, although the first and second conductive layers 111 and 112 may include the same material, the first and second conductive layers 111 and 112 have different grain sizes. The grain size of the first conductive layer 111 may be smaller. In addition, the grain size of the second conductive layer 112 may be greater. In this case, the grain sizes of the first and second conductive layers 111 and 112 may have the ratio of about 1:1.25 to 1:2.

Accordingly, the first conductive layer 111 has a dense film structure having higher density, and may have a high mechanical characteristic. In contrast, although the second conductive layer 112 is a film having lower density, the second conductive layer 112 may have high conductivity.

Similarly, the third conductive layer 113 has a grain size different from that of the second conductive layer 112. In other words, the grain size of the third conductive layer 113 may be smaller than the grain size of the second conductive layer 112.

In addition, the fourth conductive layer 114 has a grain size different from that of the third conductive layer 113. In other words, the grain size of the fourth conductive layer 114 may be greater than the grain size of the third conductive layer 113.

Since the adjacent conductive layers have grain sizes different from each other, the adjacent conductive layers may have electrical and mechanical properties different from each other. For example, the adjacent conductive layers may have different conductivities and mechanical strengths.

In the rear electrode layer 110, the conductive layers 111 and 113 having smaller grain sizes and the conductive layers 112 and 114 having greater grain sizes are alternately stacked on each other.

For example, the grain size of the first conductive layer 111 may correspond to the grain size of the third conductive layer 113. In addition, the grain size of the second conductive layer 112 may correspond to the grain size of the fourth conductive layer 114.

Accordingly, the rear electrode layer 110 may have a structure in which the conductive layers 111 and 113 having higher density are alternately stacked on the conductive layers 112 and 114 having higher conductivity. In other words, the rear electrode layer 110 may include at least three conductive layers 111 to 114.

In addition, the conductive layers 111 and 113 with smaller grain sizes are formed at higher density, thereby improving adhesion strength between the substrate 100 and the conductive layers 112 and 114 adjacent to the conductive layers 111 and 113. Since the conductive layers 112 and 114 with greater grain sizes have lower surface resistance, the conductivity of the rear electrode layer 110 can be enhanced.

The conductive layers 111 to 114 may be formed through a sputtering process employing a Mo target. In more detail, the conductive layers 111 to 114 may be formed through one sputtering process in a process chamber.

As shown in FIG. 1, the solar cell fabrication apparatus according to the embodiment may include a loading chamber 10 to receive the substrate 100, a process chamber 20 to deposit a thin film on the substrate 100, and an unloading chamber 30 to discharge the substrate 100.

In the process chamber 20, a material to form a layer may serve as a cathode 25, and the substrate 100 may serve as an anode.

The cathode 25 includes at least two cathodes C1, C2, . . . and C(2n) in line with each other, and the cathodes C1, C2, . . . and C(2n) may receive different power. For example, the cathode 25 includes cathodes C1, . . . and C(2n−1) to receive lower power, and cathodes C2, . . . and C(2n) to receive high power.

The cathodes C1, . . . and C(2n−1) to receive lower power are alternately aligned with the cathodes C2, . . . and C(2n) to receive high power. In other words, the cathodes C1, C2, . . . and C(2n) may be arranged in the sequence of the first cathode C1, the second cathode C2, . . . the (2n−1)^{th} cathode C(2n−1), and the 2n^{th} cathode C(2n).

The process chamber 20 for the sputtering process includes paired cathodes 25 to receive different power. The paired cathodes 25 include the cathodes C1, . . . and C(2n−1) to receive low power and the cathodes C2, . . . and C(2n) to receive high power. In other words, at last one pair of cathodes 25 may be arranged.

The substrate 100 moves through the lower portion of the low-power cathodes C1, . . . and C(2n−1) and the high-power cathodes C2, . . . and C(2n), and the conductive layers 111, 112, 113, and 114 may be stacked on the substrate 100 due to the different power.

In other words, the conductive layers 111 and 113 having high density are deposited on the substrate 100 due to the low-power cathodes C1, . . . and C(2n−1), and the conductive layers 112 an 114 having low surface resistance are deposited due to the high-power cathodes C2, . . . and C(2n).

For example, low power of 1 kW to 2 kW may be applied to the low-power cathodes C1, . . . and C(2n−1), and high power of 4 kW to 10 kW may be applied to the high power cathodes C2, . . . and C(2n). The sputtering process may be performed while maintaining the pressure of the process chamber 20 in the range of about 3 mTorr to 10 mTorr.

The average grain size of the first conductive layer 111 is in the range of about 15 nm to about 20 nm, and the average grain size of the second conductive layer 112 may be in the range of about 25 nm to about 30 nm. In addition, the first conductive layer 111 may have a thickness of about 30 nm to about 40 nm, and the second conductive layer 112 has a thickness of about 50 nm to about 60 nm.

The first conductive layer 111 formed due to the low power has the form of a film including small crystalline grains, so that the first conductive layer 111 may have high density. Accordingly, the adhesion strength between the substrate 100 and the first conductive layer 111 can be ensured.

The second conductive layer 112 formed due to high power has the form of a film including crystalline grains greater than those of the first conductive layer 111, thereby reducing resistivity. Accordingly, the conductivity of the rear electrode layer 110 can be enhanced.

At least one pair of the first and second cathodes C1 and C2, . . . and the (2n−1)^{th} cathode C(2n−1) and the 2n^{th} cathode (C(2n)) are alternately aligned with each other. Accordingly, the third conductive layer 113 and the fourth conductive layer 114 can be sequentially formed on the second conductive layer 112.

Since the first conductive layer 111 formed due to the first cathode C1 or the third cathode C3 can be filled in voids of the second conductive layer 112 formed due to the second cathode C2, the surface resistance and the adhesion strength inside the rear electrode layer 110 can be improved.

Since the low-power cathodes C1, . . . and C(2n−1) and the high-power cathodes C2, . . . and C(2n) are formed in one chamber, the rear electrode layer 110 can be formed through one process. Accordingly, the process idle time can be reduced when forming the rear electrode layer 110, so that the productivity can be improved.

Differently from FIG. 1, the solar cell fabrication apparatus according to the embodiment includes the first cathodes to receive low power and the second cathodes to receive high power, and the substrate 100 may reciprocate below the first and second cathodes at least two times. Accordingly, the rear electrode layer 110 including at least four conductive layers may be formed on the substrate 100.

Hereinafter, the operation of the process chamber will be described in more detail with reference to FIGS. 1 to 3. The substrate 100, which is introduced into the process chamber 20 by the loading chamber 10, sequentially passes through the first and second cathodes C1 and C2.

For example, the substrate 100 may include glass, and the rear electrode layer 110 stacked on the substrate 100 may include Mo.

If power is applied to the process chamber, reaction gas collides with electrons emitted from the cathodes C1, . . . and C(2n) so that the reaction gas is excited and changed into ions. The ions are drawn to the cathodes C1, . . . and C(2n) and collide with a target used to form a layer. In this case, the ion particles have energy, and the energy is transitted to the target used to form the layer upon the collision. When the transitted energy overcomes the bond strength and a work function of elements constituting the target, plasma is discharged, and particles of metallic grains are stacked on the substrate 100.

In this case, targets placed corresponding to the cathodes C1, . . . and C(2n) may include the same material, for example, Mo. In other words, the targets include the same material, such as Mo, to form the conductive layers 111, 112, 113, and 114. In more detail, the targets may include Mo.

Based on such an operation, the first conductive layer 111 is deposited on the substrate 100 moving below the first cathode C1.

The first conductive layer 111 may be deposited with small grain size on the substrate 100 as low power is applied to the target. Accordingly, the first conductive layer 111 may be densely deposited, and may improve an adhesion property.

Next, the second conductive layer 112 is deposited on the substrate 100 moving below the second cathode C2. The second conductive layer 112 is formed on the first conductive layer 111.

The second conductive layer 112 may be deposited with grain size greater than that of the first conductive layer 111 as high power is applied to the target. Accordingly, the second conductive layer 112 can improve conductivity.

As described above, the grain size of the first conductive layer 111 may be in the range of about 15 nm to about 20 nm, and the grain size of the second conductive layer 112 may be in the range of about 25 nm to about 30 nm. In other words, since the grains of the first conductive layer 111 are formed in small size, the first conductive layer 111 is deposited at high density. The second conductive layer 112 have grains greater than those of the first conductive layer 111, thereby representing high conductivity.

In addition, similarly, the third conductive layer 113 may be formed on the second conductive layer 112 due to the third cathode C3, and the fourth conductive layer 114 may be formed on the third conductive layer 113 due to the fourth cathode C4. In this case, the grain size of the third conductive layer 113 is in the range of about 15 nm to about 20 nm, and the grain size of the fourth conductive layer 114 may be in the range of about 25 nm to about 30 nm. In addition, the thickness of the third conductive layer 113 may be in the range of about 30 nm to about 40 nm, and the thickness of the fourth conductive layer 114 may be in the range of about 50 nm to about 60 nm. In such a manner, the rear electrode layer 110 may include three to ten layers.

Referring to FIG. 3, a light absorbing layer 120 is formed on the rear electrode layer 110.

The light absorbing layer 120 includes Ib-IIIb-VIb-based compound.

In more detail, the light absorbing layer 120 may include Cu—In—Ga—Se₂ (CIGS)-based compound or Cu—In—Se₂ (CIS)-based compound.

For example, in order to form the light absorbing layer 120, a CIG-based metal precursor layer is formed on the rear electrode layer 110 by using a Cu target, an In target, and a Ga target.

Thereafter, the metal precursor layer reacts with Se through a selenization process, thereby forming a CIGS-based light absorbing layer 120.

In addition, the light absorbing layer 120 may be formed through a co-evaporation process using Cu, In, Ga, and Se.

For example, the light absorbing layer 120 may be formed at the thickness of about 1000 nm to about 2000 nm.

The light absorbing layer 120 receives external light and converts the external light into electrical energy. The light absorbing layer 120 generates photoelectro-motive force due to a photovoltaic effect.

Referring to FIG. 4, a buffer layer 130 and a high-resistance buffer layer 140 are formed on the light absorbing layer 120.

The buffer layer 130 may include at least one layer formed on the light absorbing layer 120. The buffer layer 130 may be formed by stacking cadmium sulfide (CdS).

In this case, the buffer layer 130 is an N-type semiconductor layer, and the light absorbing layer 120 is a P-type semiconductor layer. Accordingly, the light absorbing layer 120 and the buffer layer 130 form a PN junction.

The buffer layer 130 may further includes a ZnO layer formed on the CdS layer through a sputtering process employing a ZnO target.

The high resistance buffer layer 140 may be provided in the form of a transparent layer on the buffer layer 130.

For example, the high resistance buffer layer 140 may include one of indium tin oxide (ITO), zinc oxide (ZnO), and intrinsic zinc oxide (i-ZnO).

The buffer layer 130 and the high resistance buffer layer 140 are interposed between the light absorbing layer 120 and a front electrode layer that is formed in the following process.

In other words, since the light absorbing layer 130 and the front electrode have great difference in a lattice constant and an energy band gap, the buffer layer 130 and the high resistance buffer layer 140 having a band gap placed between the band gaps of the light absorbing layer 130 and the front electrode are interposed between the light absorbing layer 130 and the front electrode, thereby forming superior junction between the light absorbing layer 130 and the front electrode.

According to the embodiment, two buffer layers 130 and 140 are formed on the light absorbing layer 120, but the embodiment is not limited thereto. In this case, only one buffer layer may be formed.

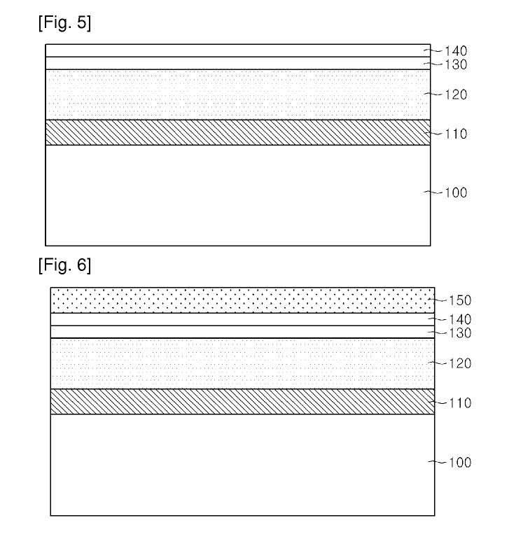

Referring to FIG. 5, a transparent conductive material is deposited on the high resistance buffer layer 140, thereby forming a front electrode layer 150.

The front electrode layer 150 may include ZnO or ITO doped with impurities such as aluminum (Al), alumina (Al₂O₃), magnesium (Mg), and gallium (Ga).

For example, the front electrode layer 150 may be formed by using ZnO doped with Al or Al₂O₃ through a sputtering process, so that an electrode having a low resistance value can be formed.

In other words, the front electrode layer 150 is a window layer forming a PN junction with the light absorbing layer 120. Since the front electrode layer 150 acts as a transparent electrode at a front surface of the solar cell, the front electrode layer 150 includes ZnO representing high light transmittance and high electrical conductivity.

According to the embodiment, both the adhesion strength and the surface resistance of the rear electrode layer 110 can be improved by using the cathodes C1, C2, . . . and C(2n) having different power in one process chamber. In other words, inter-layer adhesion strength can be improved due to the first and third conductive layers 111 and 113 formed at a high density, and the surface resistance can be improved due to the second and fourth conductive layers 112 and 114 having high conductivity.

Accordingly, adjacent conductive layers have grain sizes different from each other. Therefore, the adjacent conductive layers may have different characteristics, so that the conductive layers 111, 112, 113, and 114 constituting the rear electrode layer 110 compensate each other for inferior characteristic. Accordingly, the rear electrode layer 110 can represent improved characteristics.

For example, the third conductive layer 113 is formed on the second conductive layer 112 by low-power cathodes, so that the third conductive layer 113 can be filled in voids of the second conductive layer 112. Accordingly, internal adhesion strength can be improved. In addition, the second conductive layer 112 and the fourth conductive layer 114 can improve the conductivity of the rear electrode layer 110.

Accordingly, the solar cell according to the embodiment can represent superior performance.

The rear electrode layer 110 can be formed on the substrate 100 through one step in which different power is repeatedly applied to the first and second cathodes C1 and C2. In other words, the rear electrode layer 110 having conductivity and an adhesion property can be formed through one sputtering step in one chamber, so that the productivity can be improved.

Therefore, according to the method of fabricating the solar cell of the embodiment, a solar cell having improved performance can be effectively manufactured.

Although the exemplary embodiments have been described, it is understood that the present invention should not be limited to these exemplary embodiments but various changes and modifications can be made by one ordinary skilled in the art within the spirit and scope of the present invention as hereinafter claimed.

TABLE 1
<Experimental Example 1>

| | | process | scan | frequency | | thick- | surface | adhesion |
|---|---|---|---|---|---|---|---|---|
| step | power(kW) | pressure(mTorr) | rate(mm/m) | of scan | time(min) | ness(nm) | resistance(Ω/□) | strength(%) |
| 1 | cathode1: 1 kW | 3 | 1000 | 9 | 45 | 650 | 0.19 | 100 |
| | cathode2: 5 kW | | | | | | | |

TABLE 2
<Experimental Example 2>

| | | process | scan | frequency | | thick- | surface | adhesion |
|---|---|---|---|---|---|---|---|---|
| step | power(kW) | pressure(mTorr) | rate(mm/m) | of scan | time(min) | ness(nm) | resistance(Ω/□) | strength(%) |
| 1 | cathode1: 1 kW | 10 | 1000 | 9 | 45 | 700 | 0.21 | 100 |
| | cathode2: 5 kW | | | | | | | |

The substrate repeatedly moves to the Cathode 1 and the Cathode 2. The rear electrode layer is formed through this sputtering process. In experimental examples 1 and 2, the first and second cathodes are arranged in one sputtering chamber, and a rear electrode layer is formed through one sputtering step.

TABLE 3
<Comparison Example>

| | | process | scan | frequency | | thick- | surface | adhesion |
|---|---|---|---|---|---|---|---|---|
| step | power(kW) | pressure(mTorr) | rate(mm/m) | of scan | time(min) | ness(nm) | resistance(Ω/□) | strength(%) |
| 1 | 2 | 10 | 1000 | 9 | 45 | 420 | 2.1 | 100 |
| 2 | 5 | 3 | 1000 | 6 | 30 | 600 | 0.34 | NG100 |

In the above comparison example, step 1, in which the rear electrode layer representing improved adhesion strength is formed in the first sputtering chamber having low power and high process chamber, and step 2, in which the rear electrode layer representing improved surface resistance is formed in the second sputtering chamber having high power and low process pressure, are employed.

As shown in the above experimental examples, the rear electrode layer according to the present invention can satisfy the adhesion strength and the surface resistance through one sputtering process. In addition, the rear electrode layer is manufactured through one sputtering process, so that improved efficiency can be represented.

As the process pressure (mTorr) is increased, the deposition rate is increased so that a thick film can be formed in the same time. However, since the loss of surface resistance may be caused, the process pressure can be selected based on the productivity and the surface resistance.

### INDUSTRIAL APPLICABILITY

The solar cell and the method of fabricating the same according to the embodiment are applicable to photovoltaic fields.

1. A solar cell comprising:
a substrate;
a rear electrode layer provided on the substrate;
a light absorbing layer provided on the rear electrode; and
a front electrode layer provided on the light absorbing layer, wherein the rear electrode layer includes:
a first conductive layer provided on the substrate;
a second conductive layer provided on the first conductive layer and having a grain size different from a grain size of the first conductive layer; and
a third conductive layer provided on the second conductive layer and having a grain size different from the grain size of the second conductive layer.

2. The solar cell of claim 1, wherein the rear electrode layer further comprises a fourth conductive layer provided on the third conductive layer and having a grain size different from the grain size of the third conductive layer.

3. The solar cell of claim 2, further comprising a fifth conductive layer provided on the fourth conductive layer and having a grain size different from the grain size of the fourth conductive layer; and
a sixth conductive layer provided on the fifth conducive layer and having a grain size different from the grain size of the fourth conductive layer.

4. The solar cell of claim 1, wherein the grain size of the first conductive layer is smaller than the grain size of the second conductive layer, and
wherein the grain size of the second conductive layer is greater than the grain size of the third conductive layer.

5. The solar cell of claim 1, wherein a ratio of the grain size of the first conductive layer to the grain size of the second conductive layer is in a range of 1:1.25 to 1:2.

6. The solar cell of claim 2, wherein the grain size of the first conductive layer corresponds to the grain size of the third conductive layer, and
wherein the grain size of the second conductive layer corresponds to the grain size of the fourth conductive layer.

7. The solar cell of claim 6, wherein the first and third conductive layers have the grain size of 10 nm to 15 nm, and
wherein the second and fourth conductive layers have the grain size of 25 nm to 30 nm.

8. The solar cell of claim 2, wherein the first and third conductive layers have a thickness of 20 nm to 30 nm,
wherein the second and fourth conductive layers have a thickness of 50 nm to 60 nm, and
wherein the rear electrode layer has a thickness of 500 nm to 1500 nm.

9. A solar cell comprising
a substrate;
a rear electrode layer provided on the substrate;
a light absorbing layer provided on the rear electrode layer; and
a front electrode layer provided on the light absorbing layer,
wherein the rear electrode layer includes at least three conductive layers, and
wherein two adjacent conductive layers among the conductive layers have grain sizes different from each other.

10. The solar cell of claim 9, wherein ten conductive layers or less are provided.

11. The solar cell of claim 9, wherein the adjacent conductive layers have conductivities different from each other.

12. The solar cell of claim 9, wherein the conductive layers include a plurality of first conductive layers having a first grain size; and
a plurality of second conductive layers having a second grain size different from the first grain size,
wherein the first and second conductive layers are alternately stacked on each other.

13. The solar cell of claim 12, wherein the first conductive layers have a thickness of about 30 nm to about 40 nm,
wherein the second conductive layers have a thickness of about 50 nm to about 60 nm, and
wherein the rear electrode layer has a thickness of about 500 nm to about 1500 nm.

14. A method of fabricating a solar cell, the method comprising:
forming a rear electrode layer on a substrate;
forming a light absorbing layer on the rear electrode layer; and
forming a front electrode layer on the light absorbing layer,
wherein the forming of the rear electrode layer includes
forming a first conductive layer on the substrate by using first power;
forming a second conductive layer on the first conductive layer by using second power different from the first power; and
forming a third conductive layer on the second conductive layer by using third power different from the second power.

15. The method of claim 14, wherein the first conductive layer has a grain size different from a grain size of the second conductive layer, and
wherein the second conductive layer has a grain size different from a grain size of the third conductive layer.

16. The method of claim 14, wherein the forming of the rear electrode layer comprises:
forming a fourth conductive layer on the third conductive layer using fourth power different from the third power.

17. The method of claim 16, wherein the first power corresponds to the third power, and the second power corresponds to the fourth power.

18. The method of claim 16, wherein the first and second power are in a range of about 1 kW to about 2 kW, and
wherein the second and fourth power are in a range of about 4 kW to about 10 kW.

19. The method of claim 14, wherein targets for the first to third conductive layers include same material.

20. The method of claim 14, wherein the first to third conductive layers include molybdenum.
